(19) United States
(12) Patent Application Publication
(10) Pub. No.: US 2015/0177330 A1
(43) Pub. Date: Jun. 25, 2015

(54) METHOD FOR DETERMINING WIRELESS CHARGING REQUIREMENTS FOR A DEVICE

(71) Applicant: Cambridge Silicon Radio Limited, Cambridge (GB)

(72) Inventor: Paul Morris, Cambridge (GB)

(73) Assignee: Cambridge Silicon Radio Limited, Cambridge (GB)

(21) Appl. No.: 14/134,725

(22) Filed: Dec. 19, 2013

(51) Int. Cl. G01R 31/36; H02J 7/02; H04B 5/00; H02J 7/00

(52) U.S. Cl. CPC G01R 31/3627; H02J 7/0052; H02J 7/007; H02J 7/025; H04B 5/0031; H02J 2007/0098

(57) ABSTRACT

The present application relates to a method for determining charging requirements for a device, the method comprising: at a charger for wirelessly charging the device, detecting the presence of the device to be charged; transmitting, from the charger, a query requesting information from the device regarding the charging requirements of the device; and receiving at the charger a response from the device containing the requested information regarding the charging requirements of the device.

### TECHNICAL FIELD

The present application relates to a method for determining wireless charging requirements for a device.

### BACKGROUND TO THE INVENTION

There is increasing interest in the field of wireless charging for battery powered portable devices such as mobile telephones, tablet computers and the like. Devices capable of wireless charging need not be physically connected to a source of charging current such as a mains powered charger. Instead, such devices can simply be placed on a wireless charger, which wirelessly provides charging energy to the device, typically by inductive coupling.

There are a number of different wireless charging standards being promoted by different organisations. For example, the Wireless Power Consortium has developed a standard known as the Qi specification, whilst the Alliance for Wireless Power (A4WP) has developed its own standard. Additionally, proposals exist for using near field communications (NFC) technology for wireless charging.

At this time, none of the existing standards for wireless charging has reached a point of market dominance, and thus it is likely that different standards will coexist in the marketplace for a number of years. Accessories manufacturers will therefore need to develop charger products which support multiple different standards, to enable consumers to purchase a single charger product that is capable of charging multiple different devices that each use a different wireless charging standard.

One challenge in developing a multi-standard wireless charger is that the different charging standards have different operating characteristics. For example, the Qi standard specifies a frequency between 110 kHz and 205 kHz for charging, whilst the A4WP standard requires a charging frequency of 6.78 MHz, and any future NFC based wireless charging standard will operate at a frequency of 13.56 MHz.

In order to ensure that the correct charging standard for the device to be charged is used, a user must select the required standard at the charger. Aside from not being particularly user-friendly, this also potentially gives rise to problems if an incorrect charging standard is selected for a particular device. At best, the device will simply not charge, but in some circumstances the device may be damaged or may enter a protective mode of operation to protect itself from damage, leading to inconvenience for the user.

An alternative approach is to configure the charger to detect automatically the charging characteristics of the device to be charged. However, this requires an extensive trial and error process on the part of the charger, in which different charging frequencies and protocol exchange methods between the charger and the device to be charged are selected until the correct charging frequency and protocol exchange method are found. This delays the charging process and unnecessarily increases the power consumption of the charger.

Additionally, in wireless chargers supporting charging of multiple devices, whether or not such chargers support multiple different charging standards, a problem can arise if a second device is placed on the charger while a first device is charging. In such circumstances a charging field already exists around the charger, for charging the first device. However, the charging field will have been created to accommodate the charging needs of the first device only, and so may be not be suitable for charging the second device as well. For example, the existing charging field may be too strong for the second device, and so may damage the second device.

In view of these considerations, there exists a need for a new method by which a wireless charger can determine the charging requirements of a device to be charged.

### SUMMARY OF INVENTION

According to a first aspect of the invention there is provided a method for determining charging requirements for a device, the method comprising: at a charger for wirelessly charging the device, detecting the presence of the device to be charged; transmitting, from the charger, a query requesting information from the device regarding the charging requirements of the device; and receiving at the charger a response from the device containing the requested information regarding the charging requirements of the device.

Detecting the presence of the device to be charged may comprise receiving a signal transmitted by the device to be charged.

The signal transmitted by the device to be charged may be a response to a polling message transmitted by the charger, for example.

Alternatively, the signal transmitted by the device to be charged may comprise a polling message transmitted using a short range wireless communications protocol.

The polling message may be transmitted using a near field communications (NFC) protocol, for example.

Alternatively, the signal transmitted by the device to be charged may comprise an audible or ultrasonic sound signal.

Alternatively, the signal transmitted by the device to be charged may comprise an optical signal.

Additionally or alternatively, detecting the presence of the device to be charged may comprise receiving a signal generated by a vibration sensor of the charger indicating the presence of the device to be charged on the charger.

Additionally or alternatively, detecting the presence of the device to be charged may comprise detecting the presence of the device to be charged using a camera of the charger and associated image processing software executed by a processor of the device.

The query may be transmitted using a short range wireless communications protocol.

For example, the short range wireless communications protocol may be a near field communications (NFC) protocol.

The query may include one or more parameters selected from the group consisting of: charging standard supported; charging frequency required; preferred charging rate; current charge status; and battery capacity.

The response may include one or more parameters selected from the group consisting of: charging standard supported; charging frequency required; preferred charging rate; current charge status; and battery capacity.

The method may further comprise: adjusting a charging mode of the charger in accordance with the response received from the device at the charger.

Adjusting a charging mode of the charger in response to detecting the presence of the device to be charged may comprise reducing a charging field generated by the charger on detection of the presence of the device.

The method may further comprise: adjusting a charging mode of the charger in response to detecting removal of a device from the charger.

Adjusting a charging mode of the charger in response to detecting removal of a device from the charger may comprise increasing or reducing a charging field generated by the charger on detection of removal of the device.

According to a second aspect of the invention there is provided a wireless charger comprising: a charging system coupled to a charging antenna for generating a charging field; and a communications system, wherein the communication system is configured to: detect the presence of a device to be charged; transmit to the device to be charged a query requesting information from the device regarding the charging requirements of the device; and receive a response from the device containing the requested information regarding the charging requirements of the device.

The communications system may be configured to receive a signal transmitted by the device to be charged indicating the presence of the device to be charged.

The signal transmitted by the device to be charged may be a response to a polling message transmitted by the charger, for example.

Alternatively, the signal transmitted by the device to be charged may comprise a polling message transmitted using a short range wireless communications protocol.

The polling message may be transmitted using a near field communications (NFC) protocol.

Alternatively, the signal transmitted by the device to be charged may comprise an audible or ultrasonic sound signal.

Alternatively, the signal transmitted by the device to be charged may comprise an optical signal.

The wireless charger may further comprise a vibration sensor operative to generate a signal indicating the presence of the device to be charged on the charger.

The wireless charger may further comprise a camera and a processor executing image processing software, the image processing software being operative to cause the processor to generate a signal indicative of the presence of the device to be charged on the charger.

The communications system may be a short range wireless communications system.

For example, the wireless communications system may be a near field communications (NFC) system.

The query may include one or more parameters selected from the group consisting of: charging standard supported; charging frequency required; preferred charging rate; current charge status; and battery capacity.

The response may include one or more parameters selected from the group consisting of: charging standard supported; charging frequency required; preferred charging rate; current charge status; and battery capacity.

The wireless charger according may further comprise: a processor configured to control the charging system to adjust a charging mode of the charger in accordance with the response received from the device.

The wireless charger may further comprise: a processor configured to control the charging system to adjust a charging mode of the charger in response to detecting the presence of the device to be charged.

Adjusting a charging mode of the charger in response to detecting the presence of the device to be charged may comprise reducing a charging field generated by the charger on detection of the presence of the device.

The wireless charger may further comprise: a processor configured to control the charging system to adjust a charging mode of the charger in response to detecting removal of a device from the charger.

Adjusting a charging mode of the charger in response to detecting removal of a device from the charger comprises increasing or reducing a charging field generated by the charger on detection of removal of the device.

### BRIEF DESCRIPTION OF THE DRAWINGS

Embodiments of the invention will now be described, strictly by way of example only, with reference to the accompanying drawings, of which

FIG. 1 is a schematic representation of a wireless charging system; and

FIG. 2 is a flow diagram illustrating a method used by a wireless charger to determine the charging requirements of a wireless device to be charged.

### DESCRIPTION OF THE EMBODIMENTS

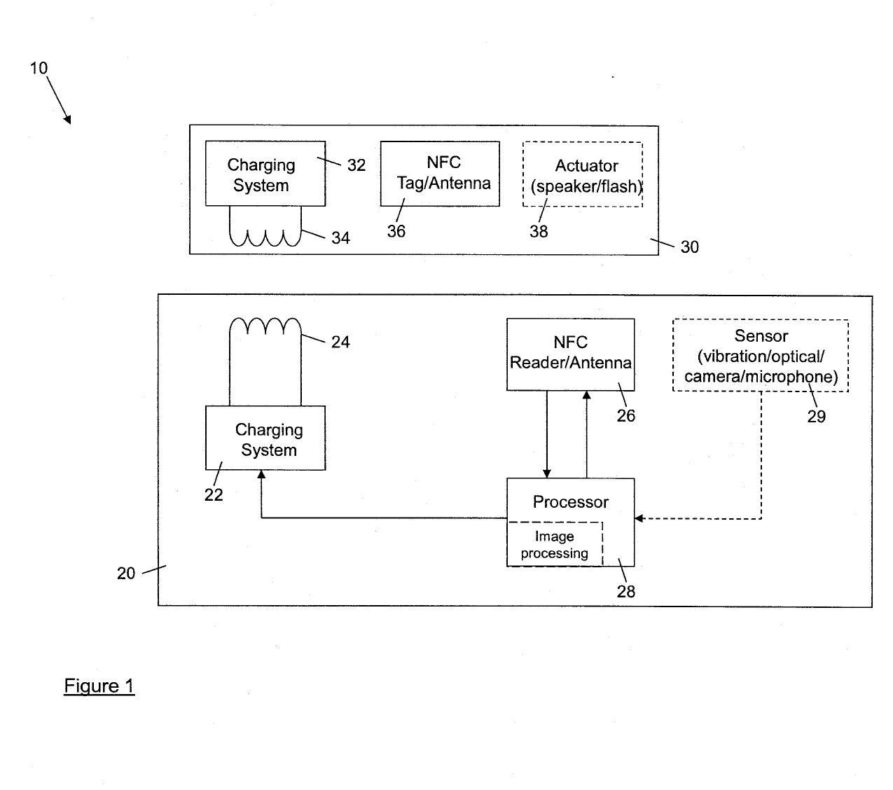

Referring first to FIG. 1, an exemplary wireless charging system is shown generally at 10. In the exemplary wireless charging system 10 of FIG. 1, a multi-standard wireless charger 20 wirelessly charges a device 30, which may be, for example, a mobile telephone or similar battery powered portable device which is capable of being charged wirelessly. The device 30 may implement a wireless charging standard such as Qi, the A4WP standard or an NFC based wireless charging standard, for example.

The multi-standard wireless charger 20 is configured to implement a plurality of wireless charging standards, such as, for example, Qi, the A4WP wireless charging standard, and an NFC based wireless charging standard. To this end, the multi-standard wireless charger 20 include a charging system 22 which is linked to a charging antenna 24. The charging system 22 supplies current to the charging antenna 24 to create a changing magnetic field (referred to as a charging field) around the charging antenna 24. The changing magnetic field around the charging antenna 24 of the charger 20 induces an electric current in an antenna of the device 30 to be charged, and this induced current can be used (directly or indirectly) to charge a battery of the device 30.

For the sake of clarity, only one charging antenna 24 is shown in FIG. 1. However, it is to be understood that the multi-standard wireless charger 20 may be provided with more than one charging antenna 24. For example, the multi-standard wireless charger 20 may be provided with one charging antenna 24 for each wireless charging standard supported by the multi-standard wireless charger. Where more than one charging antenna 24 is provided, the multi-standard wireless charger 20 may also be provided with a multiplexer to selectively connect the charging system 22 to one of the charging antennas 24.

The multi-standard wireless charger 20 also includes a short range wireless communications system 26. In the exemplary embodiment illustrated in FIG. 1 the short range wireless communication system 26 is a near field communications (NFC) system. The NFC system 26 of the multi-standard wireless charger 20 is an active device that permits the charger 20 to communicate wirelessly over a short distance with compatible NFC enabled devices.

The multi-standard wireless charger 20 also includes a processor 28, which is configured to control the operation of the charger 20 to implement a method of detecting charging requirements of a device 30, as will be described in more detail below. Although in FIG. 1 the processor 28 is shown as a standalone component, it will be appreciated that the processor 28 may be implemented in any convenient manner. For example, the processor may be incorporated into the charging system 22, or into the NFC system 26.

To enable wireless charging of the device 30, the device 30 includes a wireless charging system 32 which is connected to a charging antenna 34. The wireless charging system 32 may implement any suitable wireless charging standard.

The device 30 also includes a short range wireless communications system 36, which in the exemplary embodiment illustrated in FIG. 1 is a near field communications (NFC) system. The NFC system 36 may be, for example, a passive NFC tag, or an active NFC tag or reader. The NFC system 36 permits the device 30 to communicate wirelessly over a short distance (e.g. up to 10 cm) with compatible NFC enabled devices such as the charger 20.

As indicated above, the multi-standard wireless charger 20 is configured to implement a plurality of wireless charging standards. In contrast, the device 30 implements only one wireless charging standard. Thus, in order for the charger 20 to charge the device 30 effectively, the charger 20 must be set to the appropriate charging standard for the device 30.

In order to achieve this objective, the charger 20 communicates wirelessly with the device 30 using the respective NFC systems 26, 36 of the charger 20 and the device 30, as will be explained below.

The NFC system 26 of the multi-standard wireless charger 20 may periodically transmit polling messages. The purpose of these periodic polling messages is to detect any compatible NFC devices in the vicinity of the charger 20.

When a compatible device such as the device 30 illustrated in FIG. 1 comes into range of the NFC system 26, for example when the device 30 is brought into contact with or close to the NFC system 26 of the multi-standard wireless charger 20, the NFC system 36 of the device 30 responds to a polling message. The NFC system 26 of the wireless charger 20 then transmits a signal to the processor 28 indicating that a compatible device 30 is close by and is likely to require charging.

Alternatively, the device 30 itself may transmit NFC polling messages, via its NFC system 36, either periodically or in response to a user input indicating that the device is to enter a wireless charging mode. In this case, when the NFC system 26 of the wireless charger 20 detects an NFC polling message transmitted by the device 30, it transmits a signal to the processor 28 indicating that a compatible device 30 is close by and is likely to require charging.

Additionally or alternatively, the charger 20 may include an additional sensor sub-system 29, including one or more vibration sensors which transmit a signal to the processor 28 when a device 30 is placed on the charger 20, or when a device 30 is removed from the charger 20. The vibration sensor(s) may therefore be used as an alternative means for detecting the presence or removal of a device 30 to be charged, or as a means for confirming the presence of a device 30 to be charged following receipt of a message from the device 30 indicating the presence of the device 30. The additional sensor sub-system may further comprise one or more optical sensors such as cameras for detecting optical signals transmitted by the device 30 to be charged, and/or one or more audio sensors such as microphones for detecting audible or ultrasonic signals transmitted by the device, as will be explained in more detail below Additionally or alternatively, the optical sensor(s) and/or audio sensor(s) may be configured to transmit a signal to the processor 28 when a device 30 is placed on the charger 20, or when a device 30 is removed from the charger 20. Thus, the optical sensor(s) and/or audio sensor(s) may be used as an alternative means for detecting the presence or removal of a device 30 to be charged, or as a means for confirming the presence of a device 30 to be charged following receipt of a message from the device 30 indicating the presence of the device 30. In the case where one or more cameras form part of the additional sensor sub-system 29, image processing software may be executed by the processor 28, to permit identification of a device 30 that has been placed on or removed from the charger 20.

Once a device 30 has been detected by the charger 20 (either by the receipt of a message from the device or generation of a signal by one or more of the sensors of the additional sensor sub-system 29, or a combination of both), the processor 28 instructs the NFC system 26 to transmit a query to the detected device 30, requesting details of the charging requirements of the device 30. The query may include a request for information relating to parameters such as a charging standard supported by the device 30, a charging frequency required by the device 30, a preferred charging rate of the device 30, a current charge status of the device 30, a battery capacity of the device 30, or any other information that would assist the charger 20 in facilitating optimal charging of the device 30. The NFC system 36 of the device 30 responds with the requested details of its charging requirements, which may include the parameters such as charging standard supported, charging frequency required, preferred charging rate, current charge status, battery capacity, or any other information that would facilitate optimal charging.

On receipt of this response from the NFC system 36 of the device 30, the NFC system 26 of the charger 20 transmits a signal containing all or a subset of the received charging requirements information to the processor 28. The processor 28 in turn transmits a control signal the charging system 22 of the charger 20 to adjust a charging mode of the charging system 20. For example, the signal transmitted to the charging system 22 may include parameters such as charging standard, charging frequency, charging rate, or any other operating parameter of the charging system 22. The appropriate charging parameter(s) of the charging system 22 are then adjusted to accommodate the charging requirements of the device 30.

In the event that a valid response to the query is not received by the NFC system 26 of the charger 20, the NFC system 26 does not transmit to the processor 28 the signal indicating that a compatible device 30 is close by and is likely to require charging. Thus no adjustment is made to the charging mode of the charging system 22, and the NFC system 26 reverts to transmitting periodic polling signals. In this way, if there is no compatible device 30 in the charging range of the charger 20 (e.g. if the detected device 30 has moved out of charging range), the charging mode of the charging system 26 is not unnecessarily adjusted. On the other hand, if there is a compatible device 30 within the charging range of the charger 20 but the response to the query was incorrectly received, the device 30 will respond to a subsequent polling message and the process of querying the charging requirements of the device 30 and adjusting the charging mode of the charging system 22 can begin anew.

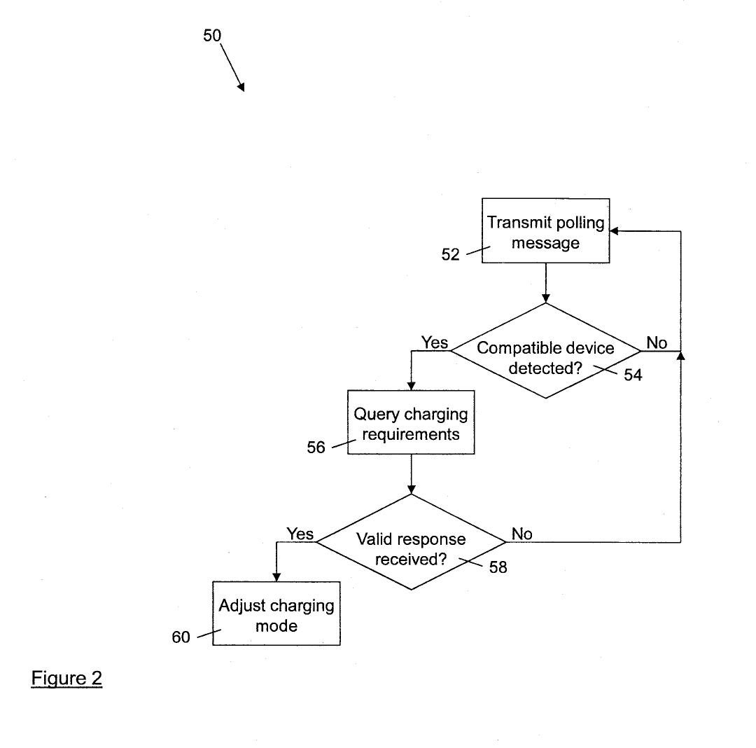

The method carried out by the multi-standard charger 20 to determine the charging requirements of a device 30 is illustrated in the flow diagram of FIG. 2. The method 50 commences with the transmission 52 of a polling message by the NFC system 26 of the charger 20. At step 54 the charger 20 determines whether a compatible device 30 has been detected, based on whether a response has been received by the NFC system 26 to the polling message. If no valid device is detected, e.g. if no valid response to the polling message has been received, the method returns to step 52, and a further polling message is transmitted after an appropriate period of time has elapsed. Of course, when a polling message is not transmitted by the NFC system 26 of the charger 20, i.e. where the system relies on receiving an alternative signal indicating the presence of the device 30 to be charged, step 52 may be omitted.

If the charger 20 determines that a compatible device 30 has been detected, the method continues to step 56, at which the NFC system 26 of the charger 20 transmits the query to the detected device 30, requesting details of the charging requirements of the device 30.

At step 58, the charger 20 determines whether a valid response has been received from the detected device 30. If so, the charging mode of the charging system 22 is adjusted at step 60 to accommodate the charging requirements of the device 30. If not, no adjustment is made to the charging mode, and the method returns to step 52, and a further polling message is transmitted after an appropriate period of time has elapsed.

The multi-standard charger 20 may be capable of charging multiple devices 30 at once. For example, the multi-standard charger 20 may include a plurality of charging systems 22 and associated charging antennas 24. Alternatively, a single charging system 22 may be provided which can charge multiple different devices 30 simultaneously through one or more charging antennas 24, or which supplies charging power to the multiple different devices 30 on a time division multiplexing basis, such that at any one time only one of the multiple devices 30 is being charged, but all of the multiple devices 30 regularly receive charging power in accordance with a predetermined charging schedule.

It will be appreciated that where one device 30 is already being charged by the multi-standard charger 20 (and indeed where the charger 20 supports only a single standard, and one device 30 is already being charged), a charging field will be established around the charging antenna 24, and this charging field will have characteristics such as field strength and frequency that are appropriate to the device 30 being charged. If a further device 30 is placed within this charging field, there is a risk that the further device 30 may be damaged, or may enter a protective mode in which wireless communications and/or charging are disabled to prevent damage to the further device. This is of course inconvenient for the user of the further device.

The method described above with reference to FIG. 2 can alleviate this problem. As the further device 30 approaches the charger 20, its presence is detected by the charger 20, either by reception by the NFC system 26 of the charger 20 of a response to a polling message, or by reception of the charger 20 of an NFC polling message or an alternative signal transmitted by the further device 30 to indicate its presence, or by vibration, optical or audio detection of the further device 30 by one or more of the sensors of the additional sensor sub-system 29. In response to the detection of the further device 30, the NFC system 26 of the charger 20 transmits a signal to the processor 28 indicating that the further device 30 is close by and is likely to require charging, To ensure that there can be no damage to the further device 30, the processor 28 transmits a control signal the charging system 22 of the charger 20 to reduce the charging field generated by the charger 20 to a level that cannot cause damage to further device 30.

The processor 28 subsequently instructs the NFC system 26 of the charger to transmit a query to the further device 30, as described above. The further device 30 responds to the query message transmitted by the NFC system 26 of the charger 20 to provide details of the charging requirements of the further device 30. If the charging requirements of the further device 30 are incompatible with the currently active charging mode, e.g. if the field strength used in the active charging mode is too great for the further device 30, the charging mode can be adjusted to accommodate the further device 30, e.g. by reducing the strength of the charging field, or, where multiple charging antennas are provided, adjusting the strength of a magnetic field around each antenna to ensure that an appropriate magnetic field strength is present around each antenna. This may have the side effect of reducing the effectiveness (e.g. reducing the speed) of the charging of the first device 30. However, this disadvantage is balanced by the reduction in the risk of damage to the further device 30. Where multiple charging antennas are provided at different positions in the charger 20, however, their individual magnetic field strengths can be tailored to generate different charging fields at different positions on the charger, to optimise charging of all devices 30 present on the charger 20 without risking damage to any one of the devices 30 that is present. Thus, the charger 20 described above may be used to charge multiple devices 30 simultaneously.

To reduce the risk of damage to a device 30 that is present on the charger 20 when a further device 30 is removed from the charger 20, the charger may be configured to detect removal of the further device 30 from the charger 20, and to reduce the charging field(s) generated by the charging antenna(s) of the charger 20 to a safe level, before issuing a new query to the remaining device 30 and readjusting the operating mode of the charger 20 as described above to accommodate the charging requirements of the remaining device 30. The remaining device 30 may require or support an increased charging field strength, in which case readjusting the operating mode of the charger 20 may involve increasing the strength of the charging field. Conversely, the removal of the further device may lead to a requirement to reduce the strength of the charging field used to charge the remaining device 30, in which case readjusting the operating mode of the charger 20 may involve reducing the strength of the charging field. The charger 20 may detect the removal of the further device 30 by, for example, detecting a signal generated by a vibration sensor of the additional sensor sub-system 29 of the charger 20, by optical or audio detection of the further device 30 by one or more of the sensors of the additional sensor sub-system 29, or by detecting a loss of communication with the further device 30 that has been removed.

As well as reducing the risk of damage if additional devices 30 are introduced into the charging field, the method described above improves the efficiency of wireless charging.

Typically in wireless charging systems the charger must communicate at regular intervals with the device being charged, using a communications protocol such as Bluetooth® low energy, to retrieve charging information such as charging frequency required, preferred charging rate, current charge status, battery capacity and the like. Charging of the device is typically paused during these interactions, to minimise the risk of damage to the device due to overcharging. By retrieving charging information from the device 30 to be charged prior to charging, the method described above reduces the frequency with which the charger 20 must undertake such interactions with the device 30 being charged, meaning that more time can be devoted to charging the device 30, and hence faster charging.

In the exemplary system discussed above, an NFC system 26 of the charger 20 communicates with an NFC system 36 of the device 30 to be charged to determine the charging requirements of the device 30. The use of NFC based communications between the charger 20 and the device 30 to be charged is particular convenient, as an increasing number of battery powered portable devices such as mobile telephones are being supplied with NFC communication systems as standard. However, it will be appreciated that other short range communications systems could equally be used for this purpose. For example, the device 30 may be provided with a radio frequency identification (RFID) tag programmed with the charging information, which tag may be queried by a compatible RFID reader of the charger 20.

As indicated above, the system may alternatively (or additionally) make use of existing actuators of the device 30 to be charged to signal the presence or approach of the device 30.

For example, the device 30 may transmit an audible or ultrasonic signal to the charger 20 to indicate its presence or approach to the charger 20 using an inbuilt speaker of the device 30. The charger 20 detects the volume and phase of this sound signal using a microphone provided as part of the additional sensor sub-system 29 to determine the proximity of the device 30 to the charger 20, and transmits a signal to the processor 28 to indicate that the device 30 is present or is approaching.

In another example, the device 30 may transmit an optical signal to the charger 20 to indicate its presence or approach. For example, where the device 30 to be charged is a mobile telephone that includes a digital camera, the device may actuate a flash of the digital camera, once or in a predetermined sequence, to indicate to the charger 20 that the device 30 is present or is approaching. An optical sensor provided as part of the additional sensor sub-system 29 of the charger 30 detects the flash or sequence of flashes and transmits a signal to the processor 28 indicating that the device 30 is present or is approaching.

1. A method for determining charging requirements for a device, the method comprising:
at a charger for wirelessly charging the device, detecting the presence of the device to be charged;
transmitting, from the charger, a query requesting information from the device regarding the charging requirements of the device; and
receiving at the charger a response from the device containing the requested information regarding the charging requirements of the device.

2. A method according to claim 1, wherein detecting the presence of the device to be charged comprises receiving a signal transmitted by the device to be charged.

3. A method according to claim 2 wherein the signal transmitted by the device to be charged is a response to a polling message transmitted by the charger.

4. A method according to claim 2 wherein the signal transmitted by the device to be charged comprises a polling message transmitted using a short range wireless communications protocol.

5. A method according to claim 4 wherein the polling message is transmitted using a near field communications (NFC) protocol.

6. A method according to claim 2 wherein the signal transmitted by the device to be charged comprises an audible or ultrasonic sound signal.

7. A method according to claim 2 wherein the signal transmitted by the device to be charged comprises an optical signal.

8. A method according to claim 1 wherein detecting the presence of the device to be charged comprises receiving a signal generated by a vibration sensor of the charger indicating the presence of the device to be charged on the charger.

9. A method according to claim 1 wherein detecting the presence of the device to be charged comprises detecting the presence of the device to be charged using a camera of the charger and associated image processing software executed by a processor of the device.

10. A method according to claim 1, wherein the query is transmitted using a short range wireless communications protocol.

11. A method according to claim 10, wherein the short range wireless communications protocol is a near field communications (NFC) protocol.

12. A method according to claim 1, wherein the query includes one or more parameters selected from the group consisting of: charging standard supported; charging frequency required; preferred charging rate; current charge status; and battery capacity.

13. A method according to claim 13, wherein the response includes one or more parameters selected from the group consisting of: charging standard supported; charging frequency required; preferred charging rate; current charge status; and battery capacity.

14. A method according to claim 1 further comprising:
adjusting a charging mode of the charger in accordance with the response received from the device at the charger.

15. A method according to claim 1 further comprising:
adjusting a charging mode of the charger in response to detecting the presence of the device to be charged.

16. A method according to claim 15 wherein adjusting a charging mode of the charger in response to detecting the presence of the device to be charged comprises reducing a charging field generated by the charger on detection of the presence of the device.

17. A method according to claim 1 further comprising:
adjusting a charging mode of the charger in response to detecting removal of a device from the charger.

18. A method according to claim 17 wherein adjusting a charging mode of the charger in response to detecting removal of a device from the charger comprises increasing or reducing a charging field generated by the charger on detection of removal of the device.

19. A wireless charger comprising:
a charging system coupled to a charging antenna for generating a charging field; and
a communications system, wherein the communication system is configured to:
detect the presence of a device to be charged;
transmit to the device to be charged a query requesting information from the device regarding the charging requirements of the device; and
receive a response from the device containing the requested information regarding the charging requirements of the device.

20. A wireless charger according to claim 19 wherein the communications system is configured to receive a signal transmitted by the device to be charged indicating the presence of the device to be charged.

21. A wireless charger according to claim 20 wherein the signal transmitted by the device to be charged is a response to a polling message transmitted by the charger.

22. A wireless charger according to claim 20 wherein the signal transmitted by the device to be charged comprises a polling message transmitted using a short range wireless communications protocol.

23. A wireless charger according to claim 22 wherein the polling message is transmitted using a near field communications (NFC) protocol.

24. A wireless charger according to claim 19 wherein the signal transmitted by the device to be charged comprises an audible or ultrasonic sound signal.

25. A wireless charger according to claim 19 wherein the signal transmitted by the device to be charged comprises an optical signal.

26. A wireless charger according to claim 19 further comprising a vibration sensor operative to generate a signal indicating the presence of the device to be charged on the charger.

27. A wireless charger according to claim 19 further comprising a camera and a processor executing image processing software, the image processing software being operative to cause the processor to generate a signal indicative of the presence of the device to be charged on the charger.

28. A wireless charger according to claim 19, wherein the communications system is a short range wireless communications system.

29. A wireless charger according to claim 28, wherein the wireless communications system is a near field communications (NFC) system.

30. A wireless charger according to claim 19, wherein the query includes one or more parameters selected from the group consisting of: charging standard supported; charging frequency required; preferred charging rate; current charge status; and battery capacity.

31. A wireless charger according to claim 30, wherein the response includes one or more parameters selected from the group consisting of: charging standard supported; charging frequency required; preferred charging rate; current charge status; and battery capacity.

32. A wireless charger according to claim 19 further comprising:
a processor configured to control the charging system to adjust a charging mode of the charger in accordance with the response received from the device.

33. A wireless charger according to claim 19 further comprising:
a processor configured to control the charging system to adjust a charging mode of the charger in response to detecting the presence of the device to be charged.

34. A wireless charger according to claim 33 wherein adjusting a charging mode of the charger in response to detecting the presence of the device to be charged comprises reducing a charging field generated by the charger on detection of the presence of the device.

35. A wireless charger according to claim 19 further comprising:
a processor configured to control the charging system to adjust a charging mode of the charger in response to detecting removal of a device from the charger.

36. A wireless charger according to claim 35 wherein adjusting a charging mode of the charger in response to detecting removal of a device from the charger comprises increasing or reducing a charging field generated by the charger on detection of removal of the device.
